(19) United States
(12) Patent Application Publication
(10) Pub. No.: US 2015/0308608 A1
(43) Pub. Date: Oct. 29, 2015

(54) DISPLAY DEVICE CAPABLE OF ADJUSTING HEIGHT OF DEVICE

(71) Applicants: Fu Tai Hua Industry (Shenzhen) Co., Ltd., Shenzhen (CN); HON HAI PRECISION INDUSTRY CO., LTD., New Taipei (TW)

(72) Inventor: QIAN LEI, Shenzhen (CN)

(21) Appl. No.: 14/510,897

(22) Filed: Oct. 9, 2014

(30) Foreign Application Priority Data
Apr. 28, 2014 (CN) 2014101721394

(51) Int. Cl. F16M 11/10; H05K 5/00; H05K 5/02; F16M 11/04

(52) U.S. Cl. CPC F16M 11/10; F16M 11/046; H05K 5/0017; H05K 5/0217

(57) ABSTRACT

A rotatable display device which is adjustable in height includes a housing, a display, a base, a connection apparatus, a fixing apparatus, a fixing shaft, and a coil spring. The display is received in the housing. The connection apparatus is attached to the housing. The fixing apparatus is attached to the base. The fixing shaft is attached to the fixing apparatus. The coil spring is sleeved on the fixing shaft. A distal end of the coil spring is attached to the fixing apparatus and is moved up and down to take the weight of the display device at any required height.

### CROSS-REFERENCE TO RELATED APPLICATIONS

This application claims priority to Chinese Patent Application No. 201410172139.4 filed on Apr. 28, 2014, in the China Intellectual Property Office, the contents of which are incorporated by reference herein.

### FIELD

The present disclosure relates to display supports.

### BACKGROUND

A display device typically include a display and a support for supporting the display. The support is often rotationally attached to the display. The display can thus rotate relative to the support to adjust a viewing angle.

### BRIEF DESCRIPTION OF THE DRAWINGS

Implementations of the present technology will now be described, by way of example only, with reference to the attached figures.

FIG. 1 is an isometric view of a display device according to an exemplary embodiment.

FIG. 2 is an exploded isometric view of part of the display device in FIG. 1.

FIG. 3 is similar to FIG. 2, but viewed from another angle.

FIG. 4 is an exploded isometric view of an elevator mechanism of the display device in FIG. 2.

FIG. 5 is similar to FIG. 4, but viewed from another angle.

### DETAILED DESCRIPTION

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. The drawings are not necessarily to scale and the proportions of certain parts may be exaggerated to better illustrate details and features. The description is not to be considered as limiting the scope of the embodiments described herein.

Several definitions that apply throughout this disclosure will now be presented.

The term “coupled” is defined as connected, whether directly or indirectly through intervening components, and is not necessarily limited to physical connections. The connection can be such that the objects are permanently connected or releasably connected. The term “substantially” is defined to be essentially conforming to the particular dimension, shape, or other feature that the term modifies, such that the component need not be exact. For example, “substantially cylindrical” means that the object resembles a cylinder, but can have one or more deviations from a true cylinder. The term “comprising” means “including, but not necessarily limited to”; it specifically indicates open-ended inclusion or membership in a so-described combination, group, series and the like.

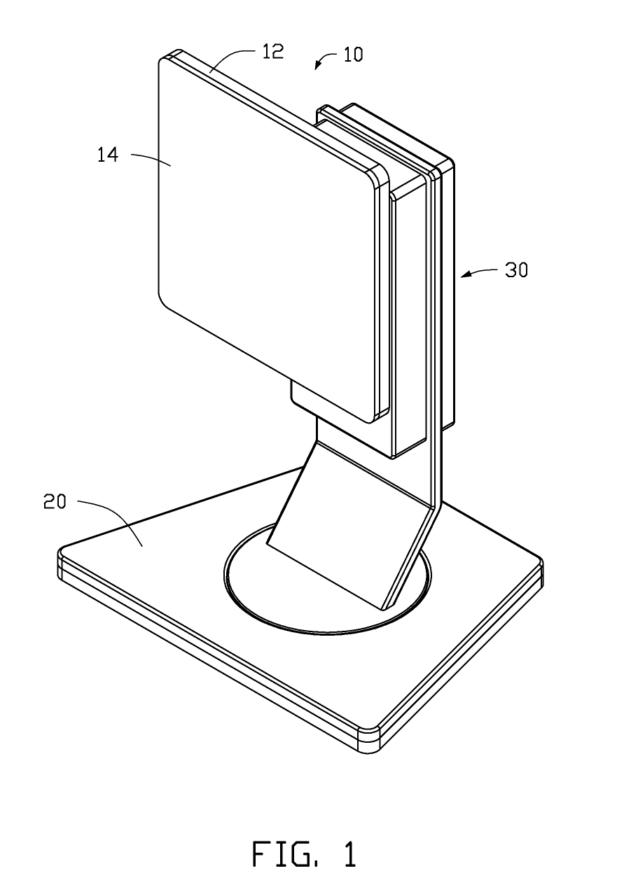

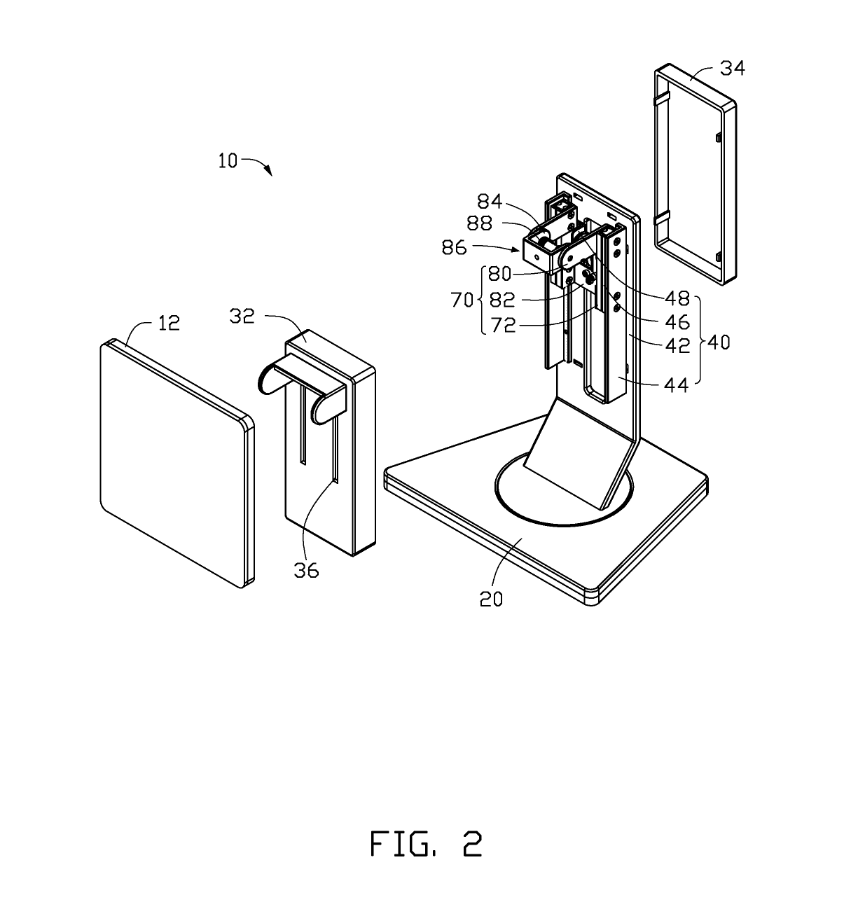

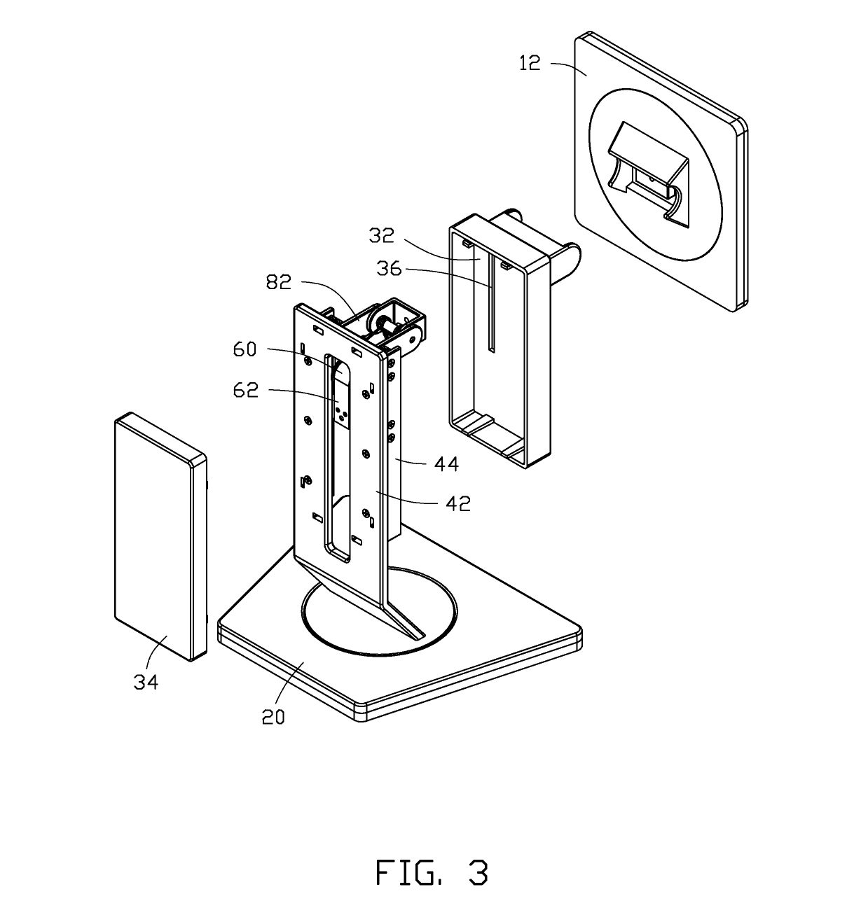

FIG. 1 illustrates a display device 10. The display device 10 includes a housing 12, a display 14 attached in the housing 12, a base 20, and an elevator mechanism 30 connected the housing 12 to the base 20. Referring to FIGS. 2 and 3, the elevator mechanism 30 includes a fixing apparatus 40, a coil spring 60, a fixing shaft 66, and a connection apparatus 70. The connection apparatus 70 is attached to the housing 12. The fixing apparatus 40 is attached to the base 20. The fixing shaft 66 is attached to the fixing apparatus 40. The coil spring 60 is sleeved on the fixing shaft 66. A distal end 62 of the coil spring 62 is attached to the fixing apparatus 70. The distal end 62 of the coil spring 60 moves up and down when the display 14 is pushed up and down to adjust a height of the display 14. The display 14 can be retained at any particular height when the display 14 is released.

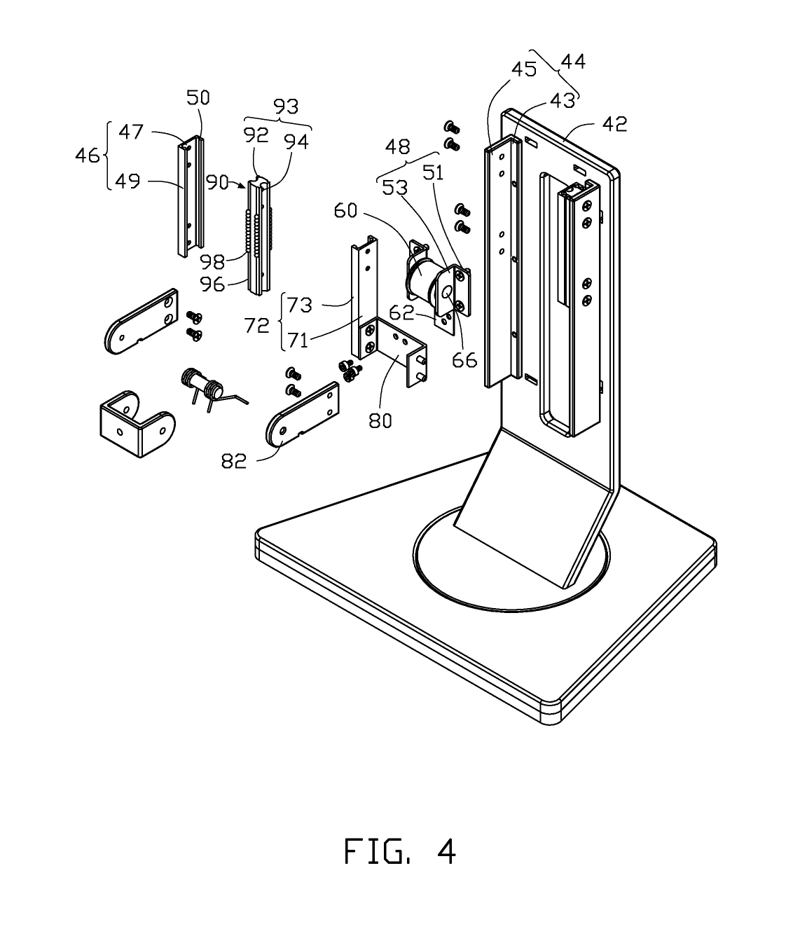

FIG. 4 illustrates that the elevator mechanism 30 further includes at least one sliding apparatus 90. The sliding apparatus 90 is attached to the connection apparatus 70. The sliding apparatus 90 is attached to the connection apparatus 40 and is slidable along the connection apparatus 40. When the display 14 is pushed down, the sliding apparatus 90 slides downward along the fixing apparatus 40. The connection apparatus 70 moves downward following the sliding apparatus. The distal end 62 of the coil spring 60 is pushed downward by the connection apparatus 70.

The fixing apparatus 40 includes a supporting plate 42, two first fixing members 44, two second fixing members 46, and two third fixing members 48. The two first fixing members 44 are attached to the supporting plate 42. The two second fixing members 46 are respectively attached to the two first fixing members 44. The two third fixing members 48 are attached to the supporting plate 42. The first fixing member 44 includes a first fixing strip 43 and a first fixing plate 45. The first fixing strip 43 is attached to and parallel to the supporting plate 42. The first fixing plate 45 is substantially perpendicularly attached to the first fixing strip 43. The first fixing member 44 is L shaped. The two first fixing members 44 are opposite to each other. The first fixing strip 43 is attached to the supporting plate 42 by bolts. The second fixing member 46 includes a second fixing plate 47 and two second fixing strips 49. The second fixing plate 47 is attached to the first fixing plate 45. The two second fixing strips 49 are attached to the second fixing plate 47. The two second fixing strips 48 each define two sliding grooves 50. The third fixing member 48 includes a third fixing strip 51 and a third fixing plate 53. The third fixing plate 53 is attached to the third strip 51. The third fixing strip 51 is attached to the supporting plate 42 by bolts. The third fixing plate 53 defines a fixing hole (not labeled). The two third fixing members 48 are aligned with each other. Two ends of the fixing shafts 66 are received in the two fixing holes.

The connection apparatus 70 includes two first connection members 72. The first connection member 72 includes a first connection plate 71 and two first connection strips 73 attached to the first connection plate 71. The two first connection strips 73 are respectively opposite to the two second fixing strips 49, and define two respective receiving spaces (not labeled). The first connection strip 73 defines a sliding slot 75. Two sliding slots 75 which are defined on the two first connection strips 73 of the connection member 72 are opposite to each other.

The elevator mechanism 30 includes two sliding apparatuses 90. The sliding apparatus 90 includes a first sliding member 93. The first sliding member 93 includes a columnar body 92 and four sliding rails 94 protruding from the columnar body 92 and parallel to it. The columnar body 92 is received in the receiving space. The columnar body 92 is attached to the first connection member 72 by bolts. Each sliding rail 94 defines an arc slot 96 extending from one end of the sliding rail 94 to the other end of the sliding rail 94. The four arc slots 96 of first sliding member 93 are opposite to the two sliding grooves 50 of the second fixing member 46 and the two sliding slots 75 of the first connection member 72. The sliding apparatus 90 further includes four rolling members 98. Two rolling members 98 are received between two sliding grooves 50 and two arc slots 96. Two other rolling members are received between two sliding slots 75 and two arc slots 96. In at least one embodiment, the rolling member 98 includes a plurality of balls as low-friction bearings.

The connection apparatus 70 includes a second connection member 80 and two third connection members 82. Two ends of the second connection member 80 are attached to the two first connection plates 71. The second connection member 80 is attached to the distal end 62 of the coil spring 60 by rivets. One end of each of the two third connection members 82 is attached to the two first connection members 72 by bolts. The other ends of the two third connection members 82 are attached to the housing 12.

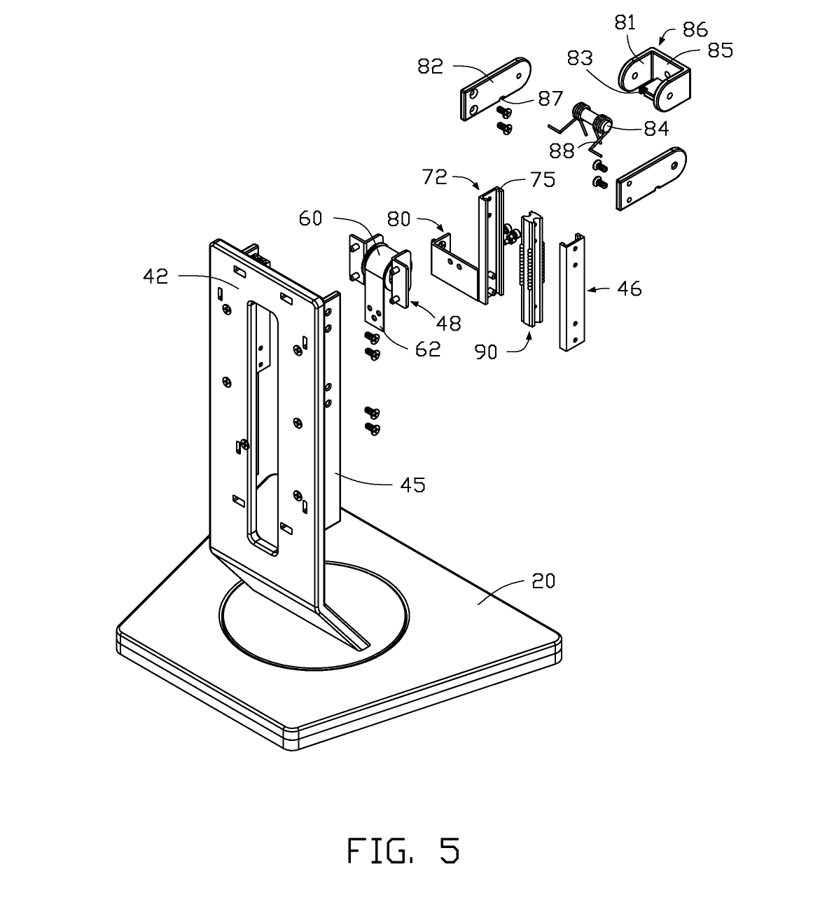

Referring to FIG. 5, the elevator mechanism 30 further includes a rotation shaft 84, a rotation member 86, and two torsion springs 88. The rotation member 96 includes two opposite rotation pieces 81, a blocking piece 83, and a connection piece 85. The blocking piece 83 is attached between two rotation pieces 81. The connection piece 85 connects two rotation pieces 81. The connection piece 85 is attached to the housing 12. The two rotation pieces 81 each define a through hole (not labeled). The rotation shaft 84 passes through the two through holes of the rotation pieces 81 to be fastened between the two third connection members 82. Thus, the display 14 is rotatable around the rotation shaft 84. The two torsion springs 88 are sleeved on the rotation shaft 84. One end of the torsion spring 88 abuts against the blocking piece 83. The other end of the torsion spring 88 abuts against the third connection member 82. The third connection member 82 defines an indentation 87. The other end of the torsion spring 88 is received in the indentation 87. Full movement of the torsion spring 88 is thus restricted.

The elevator mechanism 30 further includes a front shell 32 and a back shell 34. The front shall 32 is attached to the back shell 34. A receiving space (not labeled) is defined between the front shell 32 and the back shell 34. The fixing apparatus 40, the sliding apparatus 90, the two first connection members 72, and the second connection member 80 are all received in the receiving space. The front shell 32 defines two slots 36. The two third connection members 82 pass through the two elongated through holes 36 to be attached to the housing 12. The rotation shaft 84, the rotation member 86, and the two torsion springs 88 are arranged between the front shell 32 and the housing 12.

The embodiments shown and described above are only examples. Even though numerous characteristics and advantages of the present technology have been set forth in the foregoing description, together with details of the structure and function of the present disclosure, the disclosure is illustrative only, and changes may be made in the detail, including in matters of shape, size, and arrangement of the parts within the principles of the present disclosure, up to and including the full extent established by the broad general meaning of the terms used in the claims.

What is claimed is:

1. A display device comprising:
a housing;
a display received in the housing;
a base;
a connection apparatus attached to the housing;
a fixing apparatus attached to the base;
a fixing shaft attached to the fixing apparatus; and
a coil spring sleeved on the fixing shaft, a distal end of the coil spring attached to the fixing apparatus and movable up and down to adjust a height of the display.

2. The display device as claimed in claim 1, further comprising a sliding apparatus attached to the connection apparatus and coupled to the fixing apparatus, the sliding apparatus slidable along the fixing apparatus up and down.

3. The display device as claimed in claim 2, wherein the sliding apparatus comprises a first sliding member, the first sliding member is attached to the connection apparatus and defines at least one slot, the fixing apparatus defines at least one sliding groove opposite to the at least one slot, at least one rolling member is slidably received between the at least one sliding groove and the at least one slot.

4. The display device as claimed in claim 3, wherein the first sliding member comprises a body and four sliding rails parallel protruded from the body, four slots extends from one end of the four sliding rails to the other end of the four sliding rails.

5. The display device as claimed in claim 1, further comprising a rotation shaft attached to the connection apparatus, and a rotation member sleeved on the rotation shaft and attached to the housing.

6. The display device as claimed in claim 5, further comprising at least one torsion spring sleeved on the rotation shaft, one end of the torsion spring abutting against the rotation member, the other end of the torsion spring abutting against the connection apparatus.

7. The display device as claimed in claim 6, wherein the connection apparatus defines an indentation, the other end of the torsion spring is received in the indentation.

8. The display device as claimed in claim 6, wherein the rotation member comprises two opposite rotation pieces, a blocking piece attached between a lateral side of the two rotation pieces and a connection piece attached between one end of the two rotation pieces, the one end of the at least one torsion spring abuts against the blocking piece.

9. The display device as claimed in claim 8, wherein the two rotation pieces respectively defines a through hole, the rotation shaft passes through the two through holes to be fastened to sides of the connection apparatus, the connection piece is attached to the housing.

10. The display device as claimed in claim 1, further comprising a front shell and aback shell attached to the front shell, a receiving space defined between the front shell and the back shell, the front shell defining a slot, the fixing apparatus and a part of the connection apparatus received in the receiving space, another part of the connection apparatus passing through the slot to attach to the housing.

11. A display device comprising:
a display;
a housing configured to receive the display;
a base;
a connection apparatus attached to the housing;
a fixing apparatus attached to the base;
a fixing shaft attached to the fixing apparatus; and
a coil spring sleeved on the fixing shaft, a distal end of the coil spring attached to the fixing apparatus and movable up and down when the display is pushed up and down.

12. The display device as claimed in claim 11, further comprising a sliding apparatus attached to the connection apparatus and coupled to the fixing apparatus, the sliding apparatus slidable along the fixing apparatus up and down.

13. The display device as claimed in claim 12, wherein the sliding apparatus comprises a first sliding member, the first sliding member is attached to the connection apparatus and defines at least one slot, the fixing apparatus defines at least one sliding groove opposite to the at least one slot, at least one rolling member is slidably received between the at least one sliding groove and the at least one slot.

14. The display device as claimed in claim 13, wherein the first sliding member comprises a body and four sliding rails parallel protruded from the body, four slots extends from one end of the four sliding rails to the other end of the four sliding rails.

15. The display device as claimed in claim 11, further comprising a rotation shaft attached to the connection apparatus, and a rotation member sleeved on the rotation shaft and attached to the housing.

16. The display device as claimed in claim 15, further comprising at least one torsion spring sleeved on the rotation shaft, one end of the torsion spring abutting against the rotation member, the other end of the torsion spring abutting against the connection apparatus.

17. The display device as claimed in claim 16, wherein the connection apparatus defines an indentation, the other end of the torsion spring is received in the indentation.

18. The display device as claimed in claim 16, wherein the rotation member comprises two opposite rotation pieces, a blocking piece attached between a lateral side of the two rotation pieces and a connection piece attached between one end of the two rotation pieces, the one end of the at least one torsion spring abuts against the blocking piece.

19. The display device as claimed in claim 18, wherein the two rotation pieces respectively defines a through hole, the rotation shaft passes through the two through holes to be fastened to sides of the connection apparatus, the connection piece is attached to the housing.

20. The display device as claimed in claim 11, further comprising a front shell and aback shell attached to the front shell, a receiving space defined between the front shell and the back shell, the front shell defining a slot, the fixing apparatus and a part of the connection apparatus received in the receiving space, another part of the connection apparatus passing through the slot to attach to the housing.
